(19) United States
(12) Patent Application Publication
(10) Pub. No.: US 2013/0141128 A1
(43) Pub. Date: Jun. 6, 2013

(54) TEST DEVICE AND TEST METHOD FOR TESTING ELECTRONIC DEVICES

(71) Applicant: YI-TSANG CHEN, Tu-Cheng (TW)

(72) Inventor: YI-TSANG CHEN, Tu-Cheng (TW)

(73) Assignee: HON HAI PRECISION INDUSTRY CO., LTD., Tu-Cheng (TW)

(21) Appl. No.: 13/551,625

(22) Filed: Jul. 18, 2012

(30) Foreign Application Priority Data
Dec. 6, 2011 (TW) 100144773

(51) Int. Cl. G01R 31/01

(52) U.S. Cl. 324/750.15

(57) ABSTRACT

A test method includes: generating a start command in responses to a user input; testing each of the electronic devices in responses to the start command, and generating a test result for each of the electronic devices; obtaining a unique identifier of each of the electronic devices; obtaining the test result of each electronic device and generating a test file corresponding to each of the electronic device to record the test result; naming the test file according to the unique identifier of the corresponding electronic device; obtaining the test files, identifying the test files according to the test file name and determining whether each of the electronic devices are running in a normal state by analyzing the test result recorded in the test file. A test device using the above method is also described.

### BACKGROUND

1. Technical Field

The present disclosure relates to test devices, and particularly, to a test device and a test method for testing the running state of a number of electronic devices.

2. Description of Related Art

A data center may contain a number of servers. During the data center is running, a test device may be used to determine whether each of the servers is running in a normal state. Generally, the test device tests one server at a time, which is inconvenient.

### BRIEF DESCRIPTION OF THE DRAWINGS

Many aspects of the present disclosure should be better understood with reference to the following drawings. The units in the drawings are not necessarily drawn to scale, the emphasis instead being placed upon clearly illustrating the principles of the present disclosure. Moreover, in the drawings, like reference numerals designate corresponding portions throughout the several views.

FIG. 1 is a block diagram of a test device in accordance with an exemplary embodiment.

FIG. 2 is a flowchart of a test method in accordance with an exemplary embodiment.

### DETAILED DESCRIPTION

Embodiments of the present disclosure will now be described in detail, with reference to the accompanying drawings.

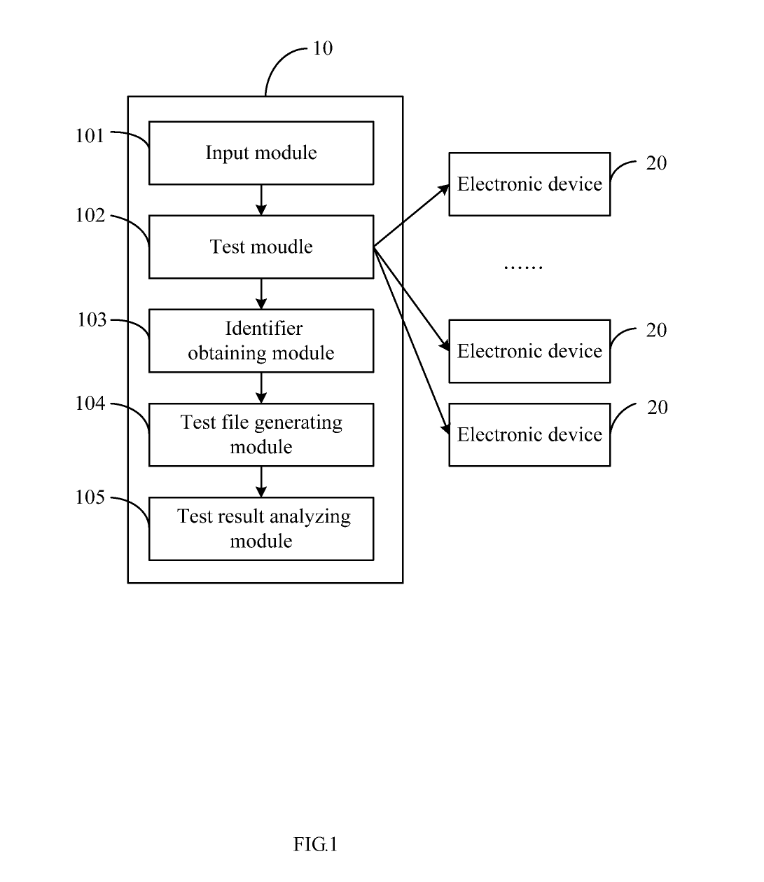

Referring to FIG. 1, in one embodiment, a test device 10 is connected to a number of electronic devices 20 by means of cables or wireless network to simultaneously test the running state of the electronic devices 20 and output a test result to an operator of the test device 10. In the embodiment, the electronic devices 20 are computer servers contained in a data center, and the test device 10 is configured to test whether the servers are running in a normal state. In detail, the test device 10 may test the voltage value, the temperature, and data transmission rate of a main board of each electronic device 20 and determines the electronic device 20 is running in a normal state if the voltage value, the temperature, and data transmission rate are all within a predetermined range, otherwise, the test device 10 determines that the electronic device 20 is running in an abnormal state.

Each of the electronic devices 20 is designated with a unique identifier. In the embodiment, the unique identifier is the fixed internet protocol (IP) address of each of the electronic device 20. In an alternative embodiment, the unique identifier may be the IP address assigned to each of the electronic device 20 by a dynamic host configuration protocol server (not shown). In other embodiments, the unique identifier may be the serial number of the central processing unit or the memory of each of the electronic device 20.

The test device 10 includes an input module 101, a test module 102, an identifier obtaining module 103, a test file generating module 104, and a test result analyzing module 105.

The input module 101 is configured to receive a user input and generate commands in responses to the user input.

The test module 102 is configured to test each of the electronic devices 20 in responses to a start command from the input module 101, and generate a test result for each electronic device 20.

The identifier obtaining module 103 is configured to obtain the unique identifier of each electronic device 20.

The test file generating module 104 obtains the test result of each electronic device 20 from the test module 101 and generates a test file for each electronic device 20 to record the obtained test result. The test file generating module 104 further names the test file according to the unique identifier of the corresponding electronic device 20. Thus, the name of each test file is associated with a corresponding electronic device 20. For example, if the IP address of an electronic device is 192.168.0.1, the test file generating module 104 may generates the test file of the electronic device 20 in a TXT format according to the test result and names the test file as: 192-168-0-1.txt.

The test result analyzing module 105 obtains the test files from the test file generating module 104, identifies the test files according to the test file names, and determines whether each of the electronic devices 20 is running in a normal state by analyzing the test result recorded in the test file. The test result analyzing module 105 further informs the operator of the test device of the test result.

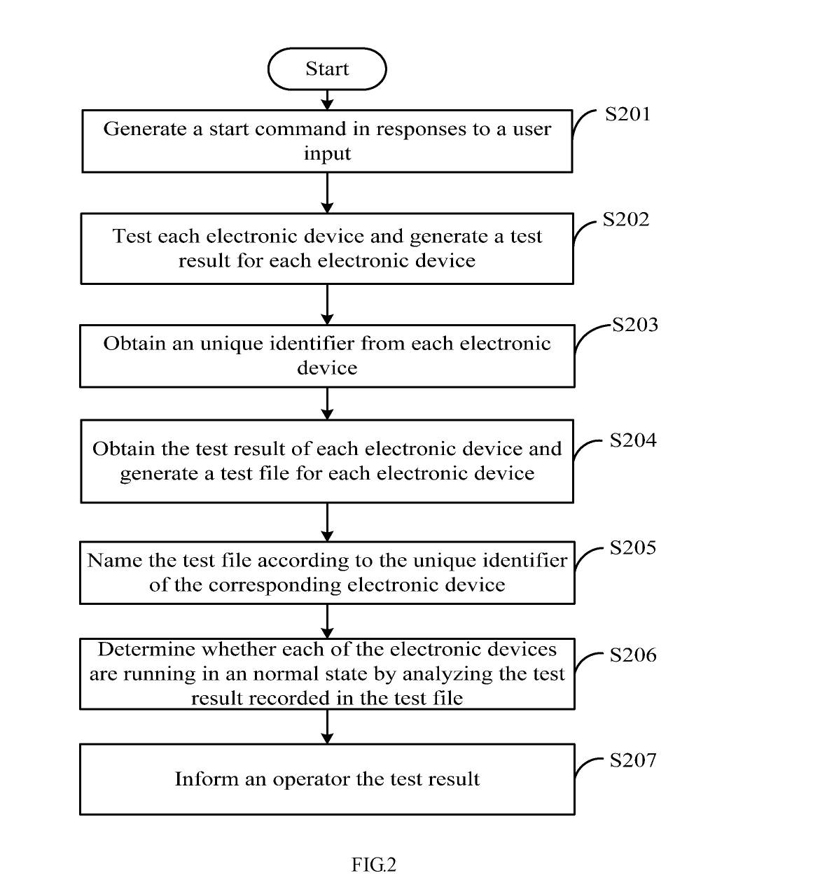

FIG. 2 is a flowchart of a test method in accordance with an exemplary embodiment.

In step S201, the input module 101 generates a start command in response to a user input.

In step S202, the test module 102 tests each of the electronic devices 20 in response to the start command from the input module 101, and generates a test result for each electronic device 20.

In step S203, the identifier obtaining module 103 obtains the unique identifier of each electronic device 20.

In step S204, the test file generating module 104 obtains the test result of each electronic device 20 from the test module 101 and generates a test file for each electronic device 20 to record the test result.

In step S205, the test file generating module 104 names the test file according to the unique identifier of the corresponding electronic device 20.

In step S206, the test result analyzing module 105 obtains the test files from the test file generating module 104, identifies the test files according to the test file name, and determines whether each of the electronic devices 20 are running in a normal state by analyzing the test result recorded in the test file.

In step S207, the test result analyzing module 105 informs the operator of the test device 10 of the test result.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A test device for simultaneously testing a plurality of electronic devices, the test device comprising:
an input module to receive user inputs and generate a start command in response to the user inputs;
a test module to test each of the electronic devices in responses to the start command from the input module, and to generate a test result for each electronic device;
an identifier obtaining module to obtain a unique identifier of each electronic device;
a test file generating module configured to:
obtain the test result of each electronic device from the test module, and
generate a test file for each electronic device to record the test result of the electronic device, and further to name the test file according to the unique identifier of the electronic device; and
a test result analyzing module configured to:
obtain the test files from the test file generating module;
identify the test files according to the test file name, and
determine whether each of the electronic devices is running in a normal state by analyzing the test results recorded in the test files.

2. The test device as described in claim 1, wherein the unique identifier is a fixed internet protocol (IP) address of each electronic device.

3. The test device as described in claim 1, wherein the unique identifier is an internet protocol (IP) address assigned to each electronic device by a dynamic host configuration protocol server.

4. The test device as described in claim 1, wherein the unique identifier is at least one of the serial number of a central processing unit of each electronic device and the serial number of a memory of each of the electronic device.

5. A test method for simultaneously testing a plurality of electronic devices, comprising:
generating a start command in response to a user input;
testing each of the electronic devices in responses to the start command, and generating a test result for each of the electronic devices;
obtaining a unique identifier of each of the electronic devices;
obtaining the test result of each electronic device and generating a test file for each electronic device to record the test result;
naming the test file according to the unique identifier of the electronic device;
obtaining the test files, identifying the test files according to the test file name and determining whether each of the electronic devices are running in a normal state by analyzing the test result recorded in the test file.

6. The test method as described in clam 5, further comprising:
informing the operator of the test device of the test result.

7. The test method as described in claim 5, wherein the unique identifier is a fixed internet protocol (IP) address of each electronic device.

8. The test method as described in claim 5, wherein the unique identifier is an internet protocol (IP) address assigned to each electronic device by a dynamic host configuration protocol server.

9. The test method as described in claim 5, wherein the unique identifier is at least one of the serial number of a central processing unit of each electronic device and the serial number of a memory of each of the electronic device.
